(19) United States
(12) Patent Application Publication
(10) Pub. No.: US 2012/0299883 A1
(43) Pub. Date: Nov. 29, 2012

(54) ORGANIC ELECTROLUMINESCENT DISPLAY APPARATUS

(75) Inventors: Noa Sumida, Chiba-shi (JP); Noriyuki Shikina, Ichihara-shi (JP)

(73) Assignee: CANON KABUSHIKI KAISHA, Tokyo (JP)

(21) Appl. No.: 13/473,900

(22) Filed: May 17, 2012

(30) Foreign Application Priority Data
May 24, 2011 (JP) 2011-115627
Mar. 27, 2012 (JP) 2012-070603

(51) Int. Cl. G09G 3/30; G09G 5/00; H05B 33/14

(52) U.S. Cl. 345/204; 313/504; 315/312; 345/76

(57) ABSTRACT

An organic electroluminescent (EL) display apparatus includes a plurality of pixels each having a first region and a second region of the same hue. The first region and the second region each include an organic EL element including a first electrode, an organic EL layer including a light-emitting layer, and a second electrode. The second region further includes a lens disposed on the light exit side of the second electrode. The organic EL element in the second region in at least part of the pixels is configured to meet 0.9<2L/λ+φ/2π<1.1.

### BACKGROUND OF THE INVENTION

1. Field of the Invention

The present invention relates to a display apparatus that uses an organic electroluminescent (EL) element, and in particular to an organic EL display apparatus in which pixels are divided into two regions of the same hue, an organic EL element is provided in each of the regions, and a lens is provided on the light exit side of the organic EL element in one of the regions.

2. Description of the Related Art

An organic EL element is known to have low light output efficiency. This is because light exits at various angles from a light-emitting layer of the organic EL element to generate a large amount of totally reflected components at the boundary between a protective film and an outside space, which confines the emitted light inside the element. In order to address such an issue, Japanese Patent Laid-Open No. 2004-039500 describes disposing an array of micro-lenses made of a resin on a silicon oxide nitride (SiNₓO_{y}) film that seals an organic EL element to improve the efficiency of light output in the forward direction.

The configuration according to Japanese Patent Laid-Open No. 2004-039500 in which the lens is disposed on the organic EL element is expected to provide a light condensing effect, in addition to allowing output of light components that would be totally reflected without the lens. Such effects improve the front luminance (the efficiency of light output in the forward direction, that is, the direction normal to a substrate) of the organic EL display apparatus. Because the luminance of the organic EL display apparatus in oblique directions is reduced, however, the configuration makes the organic EL display apparatus unsuitable for use in a scene where wide view angle characteristics are required. In a configuration in which an interference effect is imparted to the organic EL element, the luminance becomes high in the direction in which an interference effect for intensification is obtained (the direction of the optical path). Because the luminance becomes low in directions in which the interference effect for intensification is weak, however, the configuration also makes the organic EL display apparatus unsuitable for use in a scene where wide view angle characteristics are required.

In order to achieve both an improved front luminance and wide view angle characteristics, it is conceivable to provide a configuration in which pixels are divided into two regions of the same hue, an organic EL element is provided in each of the regions, and a lens is provided on the light exit side of the organic EL element in one of the regions. The configuration can provide wide view angle characteristics by emitting light from the region, of the two regions, provided with no lens, and an improved front luminance by emitting light from the region provided with the lens. However, the configuration may result in a reduction in color purity of light emitted in the forward direction depending on the conditions for optical interference, and may not reproduce good color.

The present invention provides an organic EL display apparatus in which pixels are divided into two regions of the same hue, an organic EL element is provided in each of the regions, and a lens is provided on the light exit side of the organic EL element in one of the regions. This improves the front luminance and prevents a reduction in color purity of emitted light.

### SUMMARY OF THE INVENTION

According to at least one embodiment, the present invention provides an organic electroluminescent (EL) display apparatus including a plurality of pixels each having a first region and a second region of the same hue, the first region and the second region each including an organic EL element including a first electrode, a second electrode, and an organic EL layer including a light-emitting layer and disposed between the first electrode and the second electrode, the second region further including a lens disposed on a light exit side of the second electrode, in which the organic EL element in the second region in at least part of the pixels is configured to meet the following formula:

0.9<2L/λ+φ/2π<1.1

where L indicates an optical path between the light-emitting layer and a reflective surface of the first electrode, λ indicates a wavelength of light emitted from the light-emitting layer which is intensified due to optical interference, and φ indicates an amount of phase shift caused when light emitted from the light-emitting layer is reflected by the reflective surface of the first electrode.

According to the present invention, the organic EL element in the region provided with a lens in at least part of the pixels can be configured to increase the effect to intensify light at visible-light wavelengths in the forward direction due to optical interference. This improves the front luminance across a wide view angle, and prevents a reduction in color purity of emitted light. Hence, good color with a high color purity of emitted light can be reproduced in a wide view angle.

Further features of the present invention will become apparent from the following description of exemplary embodiments with reference to the attached drawings.

### BRIEF DESCRIPTION OF THE DRAWINGS

FIGS. 1A to 1C schematically show an organic EL panel and a pixel forming a display apparatus according to the present invention.

FIG. 2 shows the luminance-view angle characteristics of an organic EL element used in the display apparatus according to the present invention.

FIGS. 3A to 3C schematically show an organic EL panel and a pixel forming a display apparatus according to a first practical example.

FIG. 4 is a pixel circuit used in the display apparatus according to the first practical example.

FIG. 5 schematically shows another example of the pixel forming the display apparatus according to the first practical example.

### DESCRIPTION OF THE EMBODIMENTS

An organic EL display apparatus according to a preferred embodiment of the present invention will be described below with reference to the drawings.

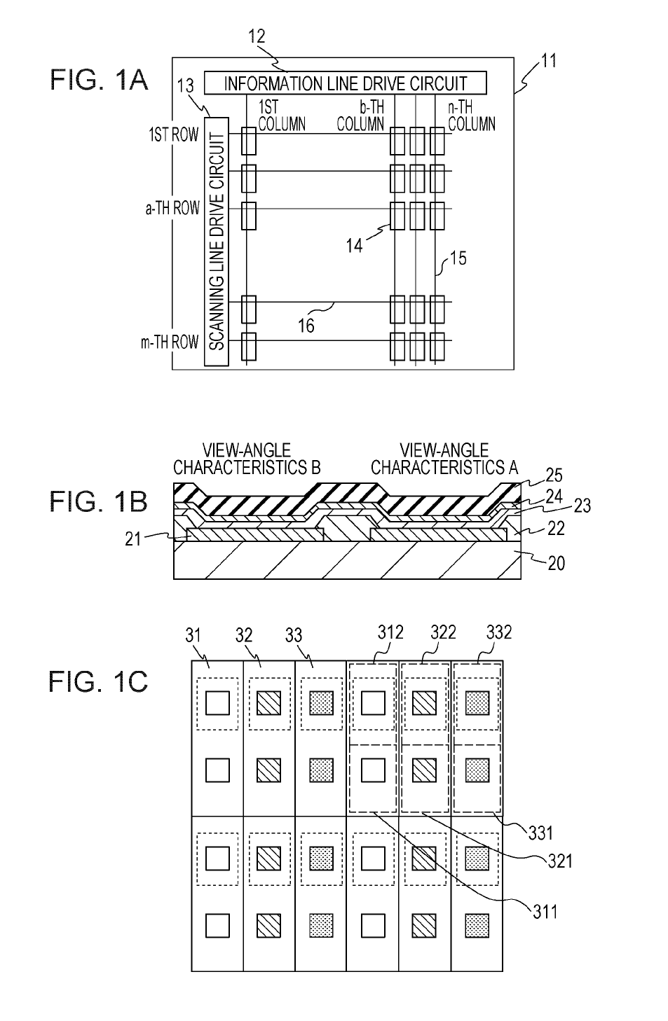

FIG. 1A is a schematic view showing an example of an organic EL panel 11 forming an organic EL display apparatus according to the present invention. The organic EL panel 11 includes a plurality of pixels disposed in a matrix (pixels in m rows and n columns), an information line drive circuit 12, a scanning line drive circuit 13, information lines 15, and scanning lines 16. The pixels are disposed at the intersections of the information lines 15 and the scanning lines 16. A pixel circuit 14 and organic EL elements are disposed in each of the pixels. The information line drive circuit 12 applies an information voltage (information signal) corresponding to image data to the information lines 15. The scanning line drive circuit 13 supplies a scanning signal to the scanning lines 16. The pixel circuit 14 supplies a drive current corresponding to the information voltage to the organic EL elements.

FIG. 1B is a partial cross-sectional view showing a portion of the organic EL panel 11 of FIG. 1A corresponding to a pixel (for example, the pixel in the a-th row and the b-th column in FIG. 1A). Each of the pixels has two regions with different view angle characteristics (view angle characteristics A and view angle characteristics B). Each “region” forming a pixel is provided with one organic EL element. In each of the pixels, first electrodes 21 patterned for each organic EL element in each region are formed on a substrate 20, and an organic EL layer (organic compound layer) 23 including a light-emitting layer and a second electrode 24 are sequentially formed on the first electrodes 21. Light emitted from the light-emitting layer is taken out directly from the second electrode side, or reflected by a reflective surface of the first electrode 21 to be taken out from the second electrode side. A region separation layer 22 that separates between the two regions is formed between the organic EL elements in the regions described above. A protective film 25 that protects the organic EL layer 23 from oxygen and water in the air is formed on the second electrode 24. One of the first electrode 21 and the second electrode 24 serves as an anode electrode, and the other serves as a cathode electrode. The first electrode 21 and the second electrode 24 may serve as an anode electrode and a cathode electrode, respectively, or may serve as a cathode electrode and an anode electrode, respectively.

The first electrode 21 is formed from a conductive metal material with a high reflectivity such as Ag, for example. Alternatively, the first electrode 21 may be formed from a stack of a layer made of such a metal material and a layer made of a transparent conductive material such as ITO (Indium-Tin-Oxide) with excellent hole injection properties. In the case where the first electrode 21 is made of metal, the interface between the metal and the organic EL layer 23 (the interface of the metal on the light-emitting layer side) serves as the reflective surface of the first electrode 21. In the case where the first electrode 21 is formed from a stack of a metal film and a transparent conductive oxide film, the interface between the metal film and the transparent conductive oxide film serves as the reflective surface of the first electrode 21. The first electrodes 21 in the same pixel may be connected to be formed continuously. In this case, no region separation layer 22 is provided between the two organic EL elements in the same pixel.

The second electrode 24 is formed in common with a plurality of organic EL elements, and formed to be semi-reflective or optically transparent so that light emitted from the light-emitting layer can be taken out of the element. In the case where the second electrode 24 is formed to be semi-reflective in order to enhance the interference effect inside the element, the second electrode 24 may be formed from a layer of a conductive metal material with excellent electron injection properties such as Ag or AgMg with a film thickness of 2 nm to 50 nm. The term “semi-reflective” means the nature to reflect part of light emitted inside the element and transmit other part of the emitted light, and corresponds to a reflectivity of 20 to 80% for visible light. The term “optically transparent” corresponds to a transmittance of 80% or more for visible light.

The organic EL layer 23 includes a single or a plurality of layers including at least the light-emitting layer. Examples of the configuration of the organic EL layer 23 include a four-layer configuration including a hole transport layer, the light-emitting layer, an electron transport layer, and an electron injection layer, and a three-layer configuration including a hole transport layer, the light-emitting layer, and an electron transport layer. The organic EL layer 23 may be formed from materials known in the art. The stacking order of the layers forming the organic EL layer 23 is reversed between a case where the first electrode 21 and the second electrode 24 serve as an anode electrode and a cathode electrode, respectively, and a case where the first electrode 21 and the second electrode 24 serve as a cathode electrode and an anode electrode, respectively.

The protective film 25 is made of an inorganic material such as silicon nitride or silicon oxynitride. Alternatively, the protective film 25 is formed from a stacked film of an inorganic material and an organic material. The film thickness of the inorganic film is preferably 0.1 μm or more and 10 μm or less, and preferably formed by a CVD method. Because the organic film is used to improve protection performance by covering foreign matter that has adhered to a surface during a process and that may not be removed, the film thickness of the organic film is preferably 1 μm or more. Although the protective film 25 is formed along the shape of the region separation layer 22 in FIG. 1B, the surface of the protective film 25 may have a flat surface. Use of the organic material facilitates making the surface of the protective film 25 flat.

Pixel circuits (not shown) are formed on the substrate 20 to drive the organic EL elements. The pixel circuits are formed from a plurality of thin-film transistors (not shown, hereinafter referred to as TFTs). The substrate 20 formed with the TFTs is covered with an interlayer insulation film (not shown) formed with contact holes for electrical connection between the TFTs and the first electrodes 21. A flattening film (not shown) that flattens a surface by absorbing surface roughness due to the pixel circuits is formed on the interlayer insulation film.

FIG. 1C shows an example of the arrangement of pixels on the organic EL panel 11 of FIG. 1A, in which an R pixel 31, a G pixel 32, and a B pixel 33 are disposed. The R pixel 31 includes an R-1 region 311 and an R-2 region 312, which have the same hue, R, and different view angle characteristics. The G pixel 32 includes a G-1 region 321 and a G-2 region 322, which have the same hue, G, and different view angle characteristics. The B pixel 33 includes a B-1 region 331 and a B-2 region 332, which have the same hue, B, and different view angle characteristics. The R pixel 31 that emits light in R color and that includes two regions with different view angle characteristics, the G pixel 32 that emits light in G color and that includes two regions with different view angle characteristics, and the B pixel 33 that emits light in B color and that includes two regions with different view angle characteristics form a single display unit. The two regions with different view angle characteristics are formed by varying the film thicknesses of the organic EL layers forming the organic EL elements in the respective regions, or by disposing a lens or a prism in only one of the regions, for example.

The organic EL display apparatus according to the present invention may be formed from an organic EL panel with three different hues as shown in FIG. 1C, or may be formed from an organic EL panel with four different hues. In the case of three hues, an organic EL panel with three hues, namely R, G, and B, including organic EL elements with three hues, namely R, G, and B, may be used, or color filters with three hues, namely R, G, and B, may be placed over a white organic EL element, for example. In the case of four hues, an organic EL panel with four hues, namely R, G, B, and W, may be used, for example.

Thus, a first feature of the present invention is that each of the pixels includes two regions with different view angle characteristics. Specifically, the R-1 region 311, the G-1 region 321, and the B-1 region 331 are formed as regions with wide view angle characteristics, and the R-2 region 312, the G-2 region 322, and the B-2 region 332 are formed as regions with a high front luminance. The term “high front luminance” means a high efficiency of light output in the forward direction, that is, the direction normal to the substrate. Hereinafter, the R-1 region 311, the G-1 region 321, and the B-1 region 331 are each referred to as a “first region”, and the R-2 region 312, the G-2 region 322, and the B-2 region 332 are each referred to as a “second region”. In order for the first region and the second region to be characterized as described above, an element with a high light condensing property is disposed on the light exit side of the organic EL element only in the second region, for example. A light condensing lens is preferably used as the element with a high light condensing property.

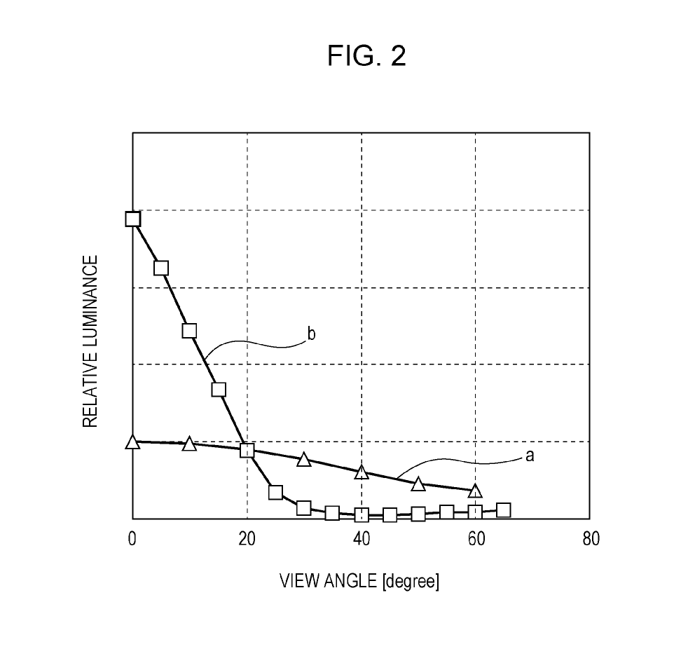

FIG. 2 is a graph showing the respective view angle characteristics of the first region and the second region in a pixel. In FIG. 2, the line (a) indicates the relative luminance-view angle characteristics of the R-1 region 311, and the line (b) indicates the relative luminance-view angle characteristics of the R-2 region 312. The luminance is represented by relative luminance values obtained when the same current is applied to the R-1 region 311 and the R-2 region 312, with the front luminance of the R-1 region 311 set to 1. It is found from FIG. 2 that the R-1 region 311 has a wider view angle. On the other hand, it is found that the R-2 region 312 has a front luminance about four times higher than that of the R-1 region 311, although the R-2 region 312 has a narrower view angle. The two regions of the G pixel 32 and the two regions of the B pixel 33 also have the same characteristics as those of FIG. 2.

Next, another feature of the present invention will be described. A second feature of the present invention is that the organic EL element in the second region in at least part of the pixels is configured to meet the following formula (1). In the formula, L₁ indicates the optical path between the light-emitting layer and the reflective surface of the first electrode 21, and φ1 indicates the sum of phase shift caused at the interface between the layers at which light is reflected (the amount of phase shift caused when light emitted from the light-emitting layer is reflected by the reflective surface of the first electrode 21).

2L₁/λ+φ₁/2π=1 (1)

The configuration that meets the above formula (1) increases the effect to intensify light at visible-light wavelengths in the forward direction due to optical interference. Such a configuration improves the front luminance, and prevents a reduction in color purity of emitted light. The details of the configuration will be described in relation to a practical example to be discussed later. The organic EL element in the first region may be also configured to meet the above formula (1).

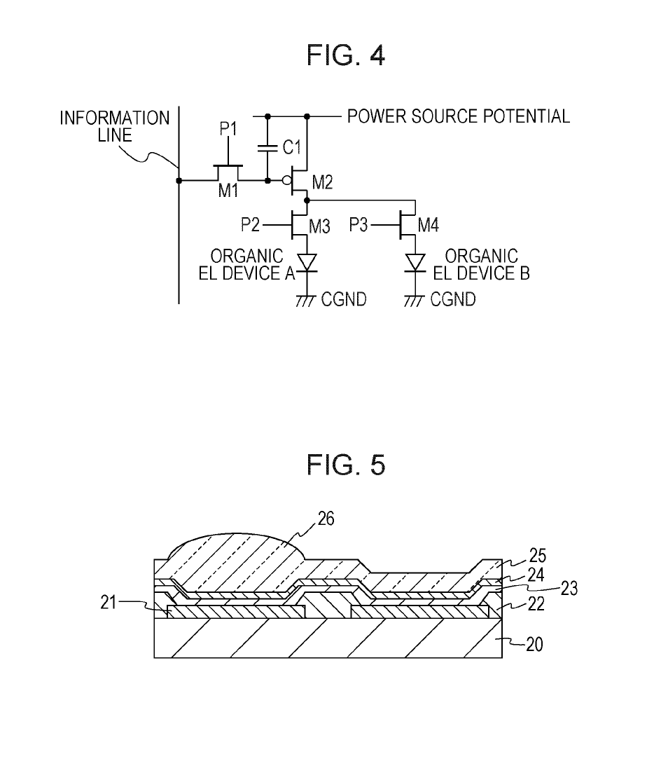

Subsequently, an operation of the organic EL panel 11 will be described. The two regions with different view angle characteristics in each of the R, G, and B pixels are driven by the pixel circuit. In the case where the first electrodes 21 in the same pixel are connected to be formed continuously, the two regions may be driven simultaneously. In the case where the first electrodes 21 in the same pixel are not connected, the two regions may be driven independently. Use of a pixel driving circuit of FIG. 4 allows the organic EL panel 11 to be driven as follows, for example.

When only the R-1 region 311, the G-1 region 321, and the B-1 region 331 with wide view angle characteristics are lit up, the organic EL panel 11 is provided with a wide view angle. When only the R-2 region 312, the G-2 region 322, and the B-2 region 332 with a high front luminance but with narrow view angle characteristics are lit up, the organic EL panel 11 is provided with a high front luminance. However, driving the two types of regions in combination (simultaneously) can achieve both an improved front luminance with high color purity and wide view angle characteristics.

In addition, power consumption can be reduced by selectively lighting up only first region or only the second region at a given time. Moreover, power consumption can be reduced by lighting up the R-2 region 312, the G-2 region 322, and the B-2 region 332 with low current that achieves a front luminance equivalent to that achieved in the case where the R-1 region 311, the G-1 region 321, and the B-1 region 331 are turned on. On the other hand, although power consumption may not be reduced, optimal image reproduction can be achieved with high front luminance and wide view angle.

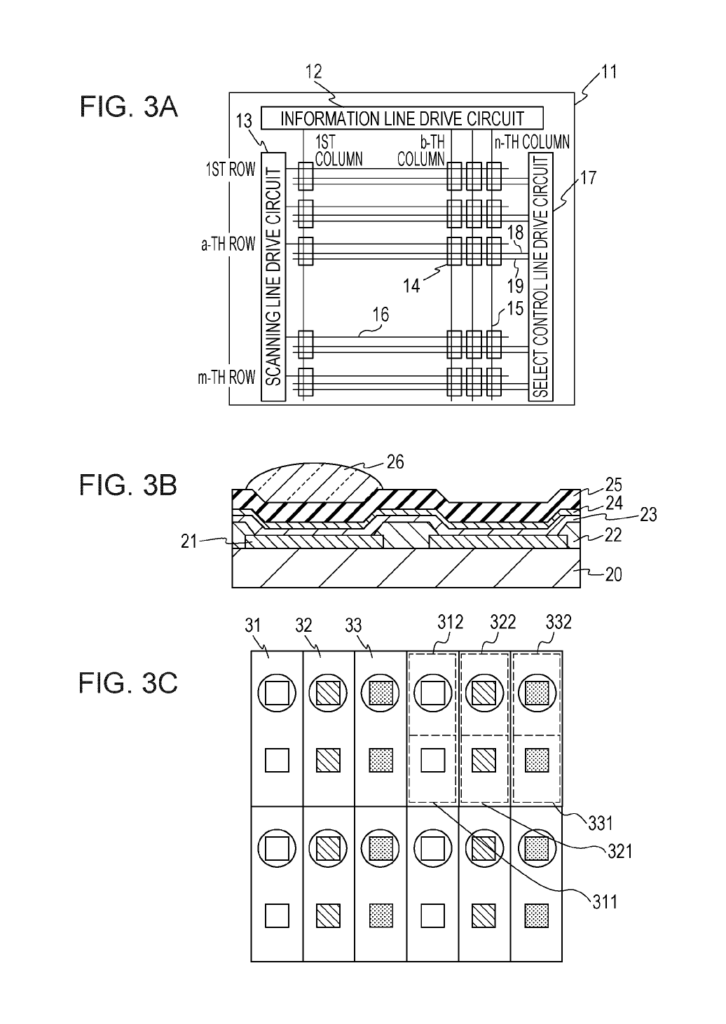

FIG. 3A is a schematic view showing the organic EL panel 11 forming the organic EL display apparatus according to a practical example. The organic EL panel 11 according to the practical example is formed by adding to the organic EL panel 11 of FIG. 1A a drive circuit 17 for select control lines for light-emitting regions and two select control lines 18 and 19. Each of the pixels corresponds to any of R, G, and B hues. The circuit of FIG. 4 is used as the pixel circuit 14. In FIG. 4, P1 denotes a scanning line, P2 denotes a select control line for an organic EL element A, and P3 denotes a select control line for an organic EL element B. An information voltage Vdata serving as an information signal is input from the information line 15. An anode electrode and a cathode electrode of the organic EL element A are connected to a drain terminal of a TFT (M3) and a grounding potential CGND, respectively. An anode electrode and a cathode electrode of the organic EL element B are connected to a drain terminal of a TFT (M4) and a grounding potential CGND, respectively.

FIG. 3B is a partial cross-sectional view showing a portion of the organic EL panel 11 according to the practical example corresponding to a pixel. Each of the pixels according to the practical example is configured by providing a lens on the light exit side (emitting side) of the organic EL element only in one of the first and second regions in the pixel of FIG. 1B. The layers under the protective film 25 according to the practical example are configured in the same way as those in FIG. 1B. In the practical example, the first electrode 21 serves as the anode electrode, and the second electrode 24 serves as the cathode electrode.

A lens 26 is formed by processing a resin material. Specifically, the lens can be formed by embossing or the like. Alternatively, the lens 26 may be formed by first forming the protective film 25 as a thick inorganic film and then etching the inorganic film into a lens shape. This results in the configuration shown in FIG. 5. Such a configuration in which the protective film 25 also serves as a lens is preferred because the protective film 25 and the lens 26 can be formed as a single layer.

When the configuration described above is used, light exiting from the organic EL layer 23 in the organic EL element B in the second region provided with the lens 26 passes through the transparent second electrode 24, and further passes through the protective film 25 and the lens 26 to exit out of the organic EL element B. The configuration provided with the lens 26 makes the exit angle close to the direction normal to the substrate compared to the configuration provided with no lens. Thus, the configuration provided with the lens 26 results in an improved effect to condense light in the direction normal to the substrate. That is, the display apparatus can utilize light in the forward direction with an enhanced efficiency. In addition, the region provided with the lens 26 makes light emitted obliquely from the light-emitting layer incident on the light exit interface at an angle closer to the vertical direction, and therefore reduces the amount of totally reflected light. As a result, the light output efficiency is also improved.

On the other hand, light exiting obliquely from the light-emitting layer of the organic EL layer 23 in the organic EL element A in the first region provided with no lens exits further more obliquely from the protective film 25. Therefore, a large amount of light cannot be taken out in the forward direction, although light can be emitted at wide angles.

FIG. 3C shows the arrangement of pixels on the organic EL panel 11 according to the practical example, which is the same as that in FIG. 1C. In the R-1 region 311, the G-1 region 321, and the B-1 region 331, the organic EL element A is flat on the light exit side. In the R-2 region 312, the G-2 region 322, and the B-2 region 332, the organic EL element B is provided with a lens on the light exit side. In the practical example, in addition, the organic EL element in the second region provided with the lens 26 in at least part of the pixels is configured to meet the above formula (1). The reasons for such a configuration will be described below.

In general, each layer such as a light-emitting layer forming an organic EL element has a film thickness of about several tens of nm, and the optical path (product of n and d) obtained by multiplying the film thickness d of each layer and the refractive index n of each layer corresponds to about several tens of percent of visible-light wavelengths (wavelengths of 350 nm or more and 780 nm or less). Therefore, visible light is subjected to significant multiple reflection and interference inside the organic EL element. The wavelength λ at which light is intensified by the interference effect (wavelength λ for intensification due to optical interference) is determined by the following formula (2):

λ=2L₁ cos θ/(m−φ₁/2π) (2)

In the formula, L₁ indicates the optical path between the light-emitting layer and the reflective surface of the first electrode 21 (hereinafter referred to as an “optical path L₁”), θ indicates the emission angle of the emitted light, m indicates the order (a positive integer) of the optical interference, and φ₁ indicates the amount of phase shift caused when the light emitted from the light-emitting layer is reflected by the reflective surface of the first electrode 21. When the material on the light incident side, of the two materials forming the interface, is defined as a medium I, the material on the other side is defined as a medium II, and the optical constants of the media I and II are defined as (n₁, k₁) and (n₂, k₂), respectively, the amount of phase shift φ₁ can be represented by the following formula (3). The optical constants can be measured using a spectral ellipsometer, for example.

φ₁=2π−tan⁻¹(2n₁−k₂/(n₁²−n₂²−k₂²)) (3)

The light emitted from the organic EL element has been obtained by adding the effect of optical interference to light emitted through recombination of carriers inside the light-emitting layer. Therefore, varying the optical path and the amount of phase shift for each layer varies the wavelength λ for intensification in the above formula (2). This makes it possible to adjust the light-emitting characteristics of the organic EL element.

In the practical example, the first electrode 21 is made of an aluminum alloy. In this case, the amount of phase shift φ₁ caused at the reflection by the reflective surface of the first electrode 21 is calculated by applying the optical constants shown in Table 1 to the above formula (3).

TABLE 1

| | | | | |
|---|---|---|---|---|
| Organic EL layer | n₁ | 1.8 | | |
| First electrode | n₂ | 0.880 | k₂ | 4.796 |

The conditions for the optical interference between the light-emitting layer of the organic EL element and the reflective surface of the first electrode 21 provided in the organic EL display apparatus according to the practical example are first considered. In the case where the emitted light between the light-emitting layer and the reflective surface of the first electrode 21 is subjected to interference, the amount of phase shift φ₁ is calculated in consideration of the fact that the emitted light is reflected by the reflective surface of the first electrode 21. In this case, the amount of phase shift φ₁ is estimated to be 3.84 (rad) (220.0 degrees) using the optical constants in Table 1 and the above formula (3).

In this event, in order for the wavelength λ for intensification to be 460 nm when the emission angle θ of the emitted light is 0°, the optical path L₁ is set to 89 nm for m=1, 319 nm for m=2, and 549 nm for m=3 using the above formula (2). As seen from the above formula (2), the wavelength λ for intensification differs in accordance with the emission angle θ of the emitted light. Tables 2 to 4 show the relationship between the emission angle θ of the emitted light and the wavelength λ for intensification at the respective optical paths L₁ (Table 2 corresponds to 89 nm, Table 3 corresponds to 319 nm, and Table 4 corresponds to 549 nm).

TABLE 2

| | | | |
|---|---|---|---|
| Emission angle | m = 1 | m = 2 | m = 3 |

| | | | | |
|---|---|---|---|---|
| 0° | 460 nm | 129 | nm | 75 nm |
| 5° | 458 nm | 128 | nm | 75 nm |
| 10° | 453 nm | 127 | nm | 74 nm |
| 15° | 444 nm | 124 | nm | 72 nm |
| 20° | 432 nm | 121 | nm | 70 nm |
| 25° | 417 nm | 117 | nm | 68 nm |
| 30° | 398 nm | 112 | nm | 65 nm |
| 35° | 377 nm | 105 | nm | 61 nm |
| 40° | 352 nm | 99 | nm | 57 nm |
| 45° | 325 nm | 91 | nm | 53 nm |
| 50° | 296 nm | 83 | nm | 48 nm |
| 55° | 264 nm | 74 | nm | 43 nm |
| 60° | 230 nm | 64 | nm | 37 nm |
| 65° | 194 nm | 54 | nm | 32 nm |
| 70° | 157 nm | 44 | nm | 26 nm |
| 75° | 119 nm | 33 | nm | 19 nm |
| 80° | 80 nm | 22 | nm | 13 nm |
| 85° | 40 nm | 11 | nm | 7 nm |

| | | | |
|---|---|---|---|
| 90° | — | — | — |

TABLE 3

| Emission angle | m = 1 | | m = 2 | m = 3 |
|---|---|---|---|---|
| 0° | 1643 | nm | 460 nm | 267 nm |
| 5° | 1637 | nm | 458 nm | 266 nm |
| 10° | 1618 | nm | 453 nm | 263 nm |
| 15° | 1587 | nm | 444 nm | 258 nm |
| 20° | 1544 | nm | 432 nm | 251 nm |
| 25° | 1489 | nm | 417 nm | 242 nm |
| 30° | 1423 | nm | 398 nm | 232 nm |
| 35° | 1346 | nm | 377 nm | 219 nm |
| 40° | 1259 | nm | 352 nm | 205 nm |
| 45° | 1162 | nm | 325 nm | 189 nm |
| 50° | 1056 | nm | 296 nm | 172 nm |
| 55° | 943 | nm | 264 nm | 153 nm |
| 60° | 822 | nm | 230 nm | 134 nm |
| 65° | 694 | nm | 194 nm | 113 nm |
| 70° | 562 | nm | 157 nm | 91 nm |
| 75° | 425 | nm | 119 nm | 69 nm |
| 80° | 285 | nm | 80 nm | 46 nm |
| 85° | 143 | nm | 40 nm | 23 nm |

| | | | |
|---|---|---|---|
| 90° | — | — | — |

TABLE 4

| Emission angle | m = 1 | m = 2 | m = 3 |
|---|---|---|---|
| 0° | 2827 nm | 791 nm | 460 nm |
| 5° | 2816 nm | 788 nm | 458 nm |
| 10° | 2784 nm | 779 nm | 453 nm |
| 15° | 2730 nm | 764 nm | 444 nm |
| 20° | 2656 nm | 744 nm | 432 nm |
| 25° | 2562 nm | 717 nm | 417 nm |
| 30° | 2448 nm | 685 nm | 398 nm |
| 35° | 2315 nm | 648 nm | 377 nm |
| 40° | 2165 nm | 606 nm | 352 nm |
| 45° | 1999 nm | 559 nm | 325 nm |
| 50° | 1817 nm | 509 nm | 296 nm |
| 55° | 1621 nm | 454 nm | 264 nm |
| 60° | 1413 nm | 396 nm | 230 nm |
| 65° | 1195 nm | 334 nm | 194 nm |
| 70° | 967 nm | 271 nm | 157 nm |
| 75° | 732 nm | 205 nm | 119 nm |
| 80° | 491 nm | 137 nm | 80 nm |
| 85° | 246 nm | 69 nm | 40 nm |
| 90° | — | — | — |

It is found from Tables 2 to 4 that the wavelength λ for intensification becomes shorter with reference to a case where the light is emitted in the forward direction of the organic EL element (the emission angle θ of the emitted light is 0°) as the emission angle θ of the emitted light becomes larger and the order m of the optical interference becomes higher.

Next, the emission angle θ of the emitted light to be incident on the lens 26 is considered. In the practical example, the lens 26 is formed on the protective film 25. The protective film 25 is made of an inorganic compound such as silicon nitride, for example, and the lens 26 is mainly made of a resin material. Therefore, there is a difference in refractive index between the protective film 25 and the lens 26. In general, an inorganic compound such as silicon nitride is higher in refractive index than a resin material. Therefore, total reflection is caused at the interface between the protective film 25 and the lens 26. The critical angle θ_{c} of the total reflection can be calculated by the following formula (4) using the refractive index nₐ of the protective film 25 and the refractive index n_{b} of the lens 26:

θ_{c}=sin⁻¹(n_{b}/nₐ) (4)

When the refractive index nₐ of the protective film 25 is 1.80 and the refractive index n_{b} of the lens 26 is 1.68, for example, the critical angle θ_{c} is 69°. Therefore, light at an emission angle θ of up to 69°, of the light emitted from the organic EL element, is incident on the lens 26. In the case where no lens 26 is provided so that the emitted light directly exits out of the display apparatus from the protective film 25, on the other hand, the refractive index of the outside (air), which equals to 1, is substituted for n_{b} in the above formula (4), along with the refractive index nₐ of the protective film 25 which is 1.80, to result in a critical angle θ_{c} of about 34°. That is, providing the lens 26 allows utilization of the emitted light at an emission angle θ of 34° to 69° which could not be utilized in the region provided with no lens 26. Thus, providing the lens 26 advantageously enhances the efficiency to utilize the emitted light. In the case where glass cap sealing is adopted, no protective film 25 is required under the lens 26. Therefore, total reflection due to a difference in refractive index among components from the organic EL layer 23 to the lens 26 can be suppressed. In this case, light reaches the entire lens 26. Whether or not the light having reached the lens 26 can be taken out is determined in accordance with the angle of the boundary between the lens 26 and the outside. Therefore, light can be taken out by elaborately designing the lens 26.

The critical angle θ_{c} at which light from the protective film 25 can be incident on the lens 26 is 69°, and the difference in refractive index between the organic EL layer 23 and the protective film 25 is small. Thus, in the following description, the emission angle θ of the emitted light in Tables 2 to 4 is substituted for the emission angle in the protective film 25 on the second electrode 24.

When the optical path L₁ is set to 89 nm in the organic EL element in the second region provided with the lens 26, the wavelength for intensification of emitted light to be incident on the lens 26 corresponds to emission angles θ of 0° to around 70° in Table 2. The wavelength for intensification is about 460 nm to 157 nm for m=1, 129 nm to 44 nm for m=2, and 75 nm to 26 nm for m=3. In general, visible light recognizable by human eyes has a wavelength range of 380 nm to 780 nm. Thus, in the case where the optical path L₁ of the organic EL element in the region provided with the lens is set to 89 nm, only emitted light that meets the conditions for m=1 to be intensified is recognized by a viewer of the display apparatus. Light that meets the conditions for m=2 and m=3 to be intensified and incident on the lens 26 has been intensified under conditions for intensifying light outside visible-light wavelengths, and therefore is not recognized by the viewer. In general, a display apparatus includes a light-emitting layer that emits light in the visible-light wavelength range. Therefore, the light-emitting characteristics of the organic EL element are not affected by the conditions for wavelength intensification for m=2 and m=3. Thus, the light-emitting characteristics of the organic EL element are determined by the conditions for optical interference for m=1.

Then, when the optical path L₁ is set to 319 nm in the organic EL element in the second region provided with the lens 26, the wavelength for intensification of emitted light to be incident on the lens 26 corresponds to emission angles θ of 0° to around 70° in Table 3. The wavelength for intensification is 1643 nm to 562 nm for m=1, 460 nm to 157 nm for m=2, and 267 nm to 91 nm for m=3. In this case, emitted light that meets the conditions for m=2 to be intensified and emitted light that meets the conditions for m=1 for emission angles θ of about 65° to 70° to be intensified affect emitted light in the visible-light wavelength range. Emitted light that meets the conditions for m=1 for emission angles θ of about 65° to 70° to be intensified has a wavelength longer than the wavelength for intensification, 460 nm, under the conditions for m=2 for an emission angle θ of 0°.

When the optical path L₁ is set to 549 nm in the organic EL element in the second region provided with the lens 26, the wavelength for intensification of emitted light to be incident on the lens 26 corresponds to emission angles θ of 0° to around 70° in Table 4. The wavelength for intensification is 2827 nm to 967 nm for m=1, 791 nm to 271 nm for m=2, and 460 nm to 157 nm for m=3. In this case, emitted light that meets the conditions for m=3 to be intensified and emitted light that meets the conditions for m=2 for emission angles θ of about 5° to 60° to be intensified affect emitted light in the visible-light wavelength range. Emitted light that meets the conditions for m=2 for emission angles θ of about 5° to 50° to be intensified has a wavelength longer than the wavelength for intensification, 460 nm, under the conditions for m=3 for an emission angle θ of 0°.

As described above, differences in optical path L₁ in the organic EL element in the second region provided with the lens 26 result in differences in wavelength for intensification of emitted light to be incident on the lens 26, even if the wavelength λ for intensification in the forward direction of the display apparatus is the same at 460 nm. Table 5 summarizes the wavelength ranges of emitted light to be incident on the lens 26 corresponding to the visible-light wavelength range discussed above.

TABLE 5

| Optical path | | m = 1 | m = 2 | m = 3 |
|---|---|---|---|---|
| 89 nm | Upper limit | 460 nm | — | — |
| | Lower limit | 398 nm | — | — |
| 319 nm | Upper limit | 694 nm | 460 nm | — |
| | Lower limit | 562 nm | 398 nm | — |
| 549 nm | Upper limit | — | 779 nm | 460 nm |
| | Lower limit | — | 396 nm | 398 nm |

When a comparison is made among the three optical paths L₁ for the organic EL element in the second region provided with the lens 26, the range of wavelength for intensification of emitted light to be incident on the lens 26 is narrow for the shortest optical path L₁ of 89 nm compared to that for the other two optical paths L₁. Then, the relationship between the effect of optical interference and the order m is considered. It is known that, in general, the effect of intensification due to optical interference becomes greater as the order m becomes lower. Therefore, in cases of m=2 and m=3 shown in Tables 3 and 4, the conditions for interference for lower orders are also met at the same time, and therefore a greater effect of intensification is obtained at the same time for wavelengths longer than the wavelength corresponding to an emission angle θ of 0°. In this case, light at various wavelengths and intensities is incident on the lens 26 compared to a case of m=1, which reduces the color purity of emitted light. Further, low-order interference is also mixed at oblique view angles, which complicates changes in color.

Hence, when the optical path L₁ is set in accordance with the conditions for m=1 in the organic EL element in the second region provided with the lens 26, a great effect of intensification due to the effect of optical interference can be utilized for the same wavelength for intensification compared to the conditions for m>1. That is, the optical path L₁ between the position of light emission and the first electrode 21 can be determined so as to meet the above formula (1).

Thus, the organic EL display apparatus according to the practical example focuses the angle dependence of the wavelength for intensification due to optical interference on the critical angle θ_{c} at the interface at which emitted light is incident on the lens 26, and variations in effect of intensification due to the order m of the optical interference. Then, for the organic EL element in the second region provided with the lens 26, the optical path between the light-emitting layer and the reflective surface of the first electrode 21 is set such that emitted light at a desired wavelength for intensification meets the conditions for optical interference for m=1. This improves the front luminance (efficiency of light output in the forward direction) and the color purity of emitted light for the organic EL element in the second region provided with the lens 26. Therefore, a display apparatus with a high color purity of emitted light, bright or good color reproducibility, and low power consumption can be provided. The wavelength for intensification to be set is not specifically limited, and the present invention may be applied to any organic EL element that includes a light-emitting layer that emits light in the visible-light wavelength range. The present invention may be applied to organic EL display apparatuses of a three primary color system for R, G, and B and of four primary color systems for three primary colors plus cyan, three primary colors plus yellow, and so forth.

In the above description, the optical path between the light-emitting layer and the reflective surface of the first electrode 21 has been discussed. In the case where the light-emitting region has expansion or distribution inside the light-emitting layer, the optical path that meets the conditions for optical interference may be adjusted as appropriate in consideration of the distribution of the light-emitting region inside the light-emitting layer.

In consideration of fluctuations in film thickness of the organic compound layer or the like that occur during film formation, the optical path L₁ may be shifted from the value that meets the formula (1) by a minute value. Specifically, the effect of the present invention can be obtained when the formula (1′) is met:

0.9<2L₁/λ+φ₁/2π<1.1 (1′)

The conditions for optical interference between the second electrode 24 and the position of light emission will be described. In this case, the amount of phase shift φ₂ is calculated in consideration of that fact that the emitted light is reflected by the second electrode 24. In the case where the second electrode 24 is formed as an Ag thin film or the like, the amount of phase shift φ₂ is estimated to be 4.21 (rad) (241.4 degrees).

The second electrode 24 is a semi-transparent film provided on the light exit side, and has a reflectivity of up to about 40%, depending on the film thickness of the second electrode 24. Therefore, emitted light is less affected compared to the conditions for interference on the side of the first electrode 21, which has a high reflectivity of 70% or more. However, the optical path may be set so as to meet various conditions for optical interference. In particular, the optical path L₂ between the second electrode 24 and the position of light emission preferably meets the following formulas (5) for the maximum peak wavelength of a spectrum emitted from the organic light-emitting element:

L₂>0 and 2L₂/λ+φ₂/2π<1 (5)

That is, the conditions for optical interference between the second electrode 24 and the position of light emission are set so as to intensify light at wavelengths shorter than the wavelength for intensification on the first electrode 21 side. In the case where the optical path L₂ is set to 33.6 nm so as to meet the formulas (5) in an organic EL element that emits light at a wavelength of 520 nm, for example, it is estimated from the amount of phase shift φ₂=4.21 (rad) that the condition for interference given by the following formula (6) is met:

2L₂/Λ+φ₂/2π=1 (6)

That is, light at a wavelength Λ=204 nm is to be intensified. Thus, light at wavelengths shorter than those of light intensified by interference on the first electrode 21 side is intensified.

Thus, in the case where the formula for optical interference on the second electrode 24 side is met with a value less than 1 (the formulas (5) are met), the range of wavelength for intensification of emitted light to be incident on the micro-lens can be made narrower. This makes it possible to achieve a display apparatus with a high color purity.

The optical path on the second electrode 24 side is preferably set to be short because this allows the total optical path between the first electrode 21 and the second electrode 24 to be set to be short.

The conditions for optical interference according to the present invention may be applied to the organic EL element in the second region provided with the lens 26 in all the pixels. This case is preferable because the effect of the present invention described above can be obtained for the organic EL element in the second region provided with the lens 26 in all the pixels. The conditions for optical interference according to the practical example may differ among colors of emitted light.

The organic EL element in the first region provided with no lens is preferably configured to meet the following formula (7). This is because the effect of intensification due to optical interference can be obtained also for the organic EL element in the first region provided with no lens to improve the color purity.

2L₁/λ+φ₁/2π=m (m is a positive integer) (7)

In consideration of fluctuations in film thickness of the organic compound layer or the like that occur during film formation, the optical path L₁ may be shifted from the value that meets the formula (7) by a minute value. Specifically, the effect of the present invention can be obtained when the formula (7′) is met:

m−0.1<2L₁/λ+φ₁/2π<m+0.1 (7′)

In the case where m is an integer of 2 or more, low-order interference is mixed at oblique view angles. Therefore, m is preferably 1.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-115627 filed May 24, 2011 and No. 2012-070603 filed Mar. 27, 2012, which are hereby incorporated by reference herein in their entirety.

What is claimed is:

1. An organic electroluminescent (EL) display apparatus, comprising:
a pixel having a first region and a second region of the same hue,
the first region and the second region each including an organic EL element including a first electrode, a second electrode, and an organic EL layer including a light-emitting layer and disposed between the first electrode and the second electrode,
the second region further including a lens disposed on a light exit side of the organic EL element,
wherein the organic EL element in the second region meets the following formula:
0.9<2L₁/λ+φ₁/2π<1.1
where L₁ indicates an optical path between the light-emitting layer and a reflective surface of the first electrode, λ indicates a wavelength of light emitted from the light-emitting layer which is intensified due to optical interference, and φ₁ indicates an amount of phase shift caused when the light is reflected by the reflective surface of the first electrode.

2. The organic EL display apparatus according to claim 1,
wherein the organic EL element in the second region meets the following formulas:
L₂>0 and 2L₂/λ+φ₂/2π<1
where L₂ indicates an optical path between the light-emitting layer and a reflective surface of the second electrode, and φ₂ indicates an amount of phase shift caused when the light emitted from the light-emitting layer is reflected by the reflective surface of the second electrode.

3. The organic EL display apparatus according to claim 1,
wherein the organic EL element in the first region meets the following formula:
m−0.1<2L₁/λ+φ₁/2π<m+0.1
where m is a positive integer.

4. The organic EL display apparatus according to claim 1,
wherein the organic EL element in the first region meets the following formula:
0.9<2L₁/λ+φ₁/2π<1.1.

5. The organic EL display apparatus according to claim 1, further comprising a pixel driving circuit configured to selectively drive the first and second regions of each pixel in accordance with a manner in which the first electrodes are connected.

6. The organic EL display apparatus according to claim 5, wherein, when the first electrodes in the first and second regions are interconnected, the pixel driving circuit drives the first and second regions simultaneously.

7. The organic EL display apparatus according to claim 5, wherein, when the first electrodes in the first and second regions are not interconnected, the pixel driving circuit drives the first and second regions independently.

8. An organic electroluminescent (EL) display apparatus, comprising:
an array of pixels arranged in a matrix of rows and columns, each pixel having a first emitting region and a second emitting region;
an organic EL element including a first electrode, a second electrode, and an organic EL layer including a light-emitting layer, the organic EL element being disposed between the first electrode and the second electrode under each of the first emitting region and second emitting region of each pixel;
a lens stacked on one of the first emitting region and second emitting region on a light emitting side of the organic EL element,
wherein the organic EL element corresponding to the one of the first emitting region and second emitting region on which the lens is tacked satisfies the following condition:
0.9<2L₁/λ+φ₁/2π<1.1
where L₁ represents an optical path between the light-emitting layer and a reflective surface of the first electrode, λ represents a wavelength emitted by the light-emitting layer, and φ₁ indicates an amount of phase shift caused when light emitted from the light-emitting layer is reflected by the reflective surface of the first electrode.
